(19) United States
(12) Patent Application Publication
(10) Pub. No.: US 2007/0137693 A1
(43) Pub. Date: Jun. 21, 2007

(54) Intermediate-band photosensitive device with quantum dots having tunneling barrier embedded in inorganic matrix

(76) Inventor: Stephen R. Forrest, Ann Arbor, MI (US)

Correspondence Address: KENYON & KENYON LLP, 1500 K STREET N.W., SUITE 700, WASHINGTON, DC, 20005, US

(21) Appl. No.: 11/304,713

(22) Filed: Dec. 16, 2005

(51) Int. Cl. H01L 31/00

(52) U.S. Cl. 136/255

(57) ABSTRACT

A plurality of quantum dots comprise a first inorganic material, and each quantum dot is coated with a second inorganic material. The coated quantum dots being are in a matrix of a third inorganic material. At least the first and third materials are photoconductive semiconductors. The second material is arranged as a tunneling barrier to require a charge carrier (an electron or a hole) at a base of the tunneling barrier in the third material to perform quantum mechanical tunneling to reach the first material within a respective quantum dot. A first quantum state in each quantum dot is between a conduction band edge and a valence band edge of the third material in which the coated quantum dots are embedded. Wave functions of the first quantum state of the plurality of quantum dots may overlap to form an intermediate band.

This invention was made with U.S. Government support under Contract No. 339-4012 awarded by U.S. Department of Energy, National Renewable Energy Laboratory. The government has certain rights in this invention.

### JOINT RESEARCH AGREEMENT

The claimed invention was made by, on behalf of, and/or in connection with one or more of the following parties to a joint university-corporation research agreement: Princeton University, The University of Southern California, and Global Photonic Energy Corporation. The agreement was in effect on and before the date the claimed invention was made, and the claimed invention was made as a result of activities undertaken within the scope of the agreement.

### FIELD OF THE INVENTION

The present invention generally relates to photosensitive optoelectronic devices. More specifically, it is directed to intermediate-band photosensitive optoelectronic devices with inorganic quantum dots providing the intermediate band in an inorganic semiconductor matrix.

### BACKGROUND

Optoelectronic devices rely on the optical and electronic properties of materials to either produce or detect electromagnetic radiation electronically or to generate electricity from ambient electromagnetic radiation.

Photosensitive optoelectronic devices convert electromagnetic radiation into an electrical signal or electricity. Solar cells, also called photovoltaic (“PV”) devices, are a type of photosensitive optoelectronic device that is specifically used to generate electrical power. Photoconductor cells are a type of photosensitive optoelectronic device that are used in conjunction with signal detection circuitry which monitors the resistance of the device to detect changes due to absorbed light. Photodetectors, which may receive an applied bias voltage, are a type of photosensitive optoelectronic device that are used in conjunction with current detecting circuits which measures the current generated when the photodetector is exposed to electromagnetic radiation.

These three classes of photosensitive optoelectronic devices may be distinguished according to whether a rectifying junction as defined below is present and also according to whether the device is operated with an external applied voltage, also known as a bias or bias voltage. A photoconductor cell does not have a rectifying junction and is normally operated with a bias. A PV device has at least one rectifying junction and is operated with no bias. A photodetector has at least one rectifying junction and is usually but not always operated with a bias.

As used herein, the term “rectifying” denotes, inter alia, that an interface has an asymmetric conduction characteristic, i.e., the interface supports electronic charge transport preferably in one direction. The term “photoconductive” generally relates to the process in which electromagnetic radiant energy is absorbed and thereby converted to excitation energy of electric charge carriers so that the carriers can conduct (i.e., transport) electric charge in a material. The term “photoconductive material” refers to semiconductor materials which are utilized for their property of absorbing electromagnetic radiation to generate electric charge carriers. When electromagnetic radiation of an appropriate energy is incident upon a photoconductive material, a photon can be absorbed to produce an excited state. There may be intervening layers, unless it is specified that the first layer is “in physical contact with” or “in direct contact with” the second layer.

In the case of photosensitive devices, the rectifying junction is referred to as a photovoltaic heterojunction. To produce internally generated electric fields at the photovoltaic heterojunction which occupy a substantial volume, the usual method is to juxtapose two layers of material with appropriately selected semi-conductive properties, especially with respect to their Fermi levels and energy band edges.

Types of inorganic photovoltaic heterojunctions include a p-n heterojunction formed at an interface of a p-type doped material and an n-type doped material, and a Schottky-barrier heterojunction formed at the interface of an inorganic photoconductive material and a metal.

In inorganic photovoltaic heterojunctions, the materials forming the heterojunction have been denoted as generally being of either n-type or p-type. Here n-type denotes that the majority carrier type is the electron. This could be viewed as a material having many electrons in relatively free energy states. The p-type denotes that the majority carrier type is the hole. Such a material has many holes in relatively free energy states.

One common feature of semiconductors and insulators is a “band gap.” The band gap is the energy difference between the highest energy level filled with electrons and the lowest energy level that is empty. In an inorganic semiconductor or inorganic insulator, this energy difference is the difference between the valence band edge E_{V} (top of the valence band) and the conduction band edge E_{C} (bottom of the conduction band). The band gap of a pure material is devoid of energy states where electrons and holes can exist. The only available carriers for conduction are the electrons and holes which have enough energy to be excited across the band gap. In general, semiconductors have a relatively small band gap in comparison to insulators.

In terms of an energy band model, excitation of a valence band electron into the conduction band creates carriers; that is, electrons are charge carriers when on the conduction-band-side of the band gap, and holes are charge carriers when on the valence-band-side of the band gap.

As used herein, a first energy level is “above,” “greater than,” or “higher than” a second energy level relative to the positions of the levels on an energy band diagram under equilibrium conditions. Energy band diagrams are a workhorse of semiconductor models. As is the convention with inorganic materials, the energy alignment of adjacent doped materials is adjusted to align the Fermi levels (E_{F}) of the respective materials, bending the vacuum level between doped-doped interfaces and doped-intrinsic interfaces.

As is the convention with energy band diagrams, it is energetically favorable for electrons to move to a lower energy level, whereas it is energetically favorable for holes to move to a higher energy level (which is a lower potential energy for a hole, but is higher relative to an energy band diagram). Put more succinctly, electrons fall down whereas holes fall up.

In inorganic semiconductors, there may be a continuum of conduction bands above the conduction band edge (E_{C}) and a continuum of valence bands below the valence band edge (E_{V}).

Carrier mobility is a significant property in inorganic and organic semiconductors. Mobility measures the ease with which a charge carrier can move through a conducting material in response to an electric field. In comparison to semiconductors, insulators generally provide poor carrier mobility.

### SUMMARY OF THE INVENTION

A plurality of quantum dots comprise a first inorganic material, and each quantum dot is coated with a second inorganic material. The coated quantum dots being are in a matrix of a third inorganic material. At least the first and third materials are photoconductive semiconductors. The second material is arranged as a tunneling barrier to require a charge carrier (an electron or a hole) at a base of the tunneling barrier in the third material to perform quantum mechanical tunneling to reach the first material within a respective quantum dot. A first quantum state in each quantum dot is between a conduction band edge and a valence band edge of the third material in which the coated quantum dots are embedded. Wave functions of the first quantum state of the plurality of quantum dots may overlap to form an intermediate band.

The first quantum state is a quantum state above a band gap of the first material in a case where the charge carrier is an electron. The first quantum state is a quantum state below the band gap of the first material in a case where the charge carrier is a hole.

Each quantum dot may also have a second quantum state. The second quantum state is above the first quantum state and within ±0.16 eV of the conduction band edge of the third material in the case where the charge carrier is the electron. The second quantum state is below the first quantum state and within ±0.16 eV of the valence band edge of the third material in the case where the charge carrier is the hole.

A height of the tunneling barrier is an absolute value of an energy level difference between a peak and the base of the tunneling barrier. A combination of the height and potential profile of the tunneling barrier and a thickness of the second material coating each quantum dot may correspond to a tunneling probability between 0.1 and 0.9 that the charge carrier will tunnel into the first material within the respective coated quantum dot from the third material. With the tunneling probability between 0.1 and 0.9, the thickness of the coating of the second material is preferably in a range of 0.1 to 10 nanometers.

More preferably, the combination of the height and potential profile of the tunneling barrier and the thickness of the second material coating each quantum dot corresponds to a tunneling probability between 0.2 and 0.5 that the charge carrier will tunnel into the first material within the respective coated quantum dot from the third material. With the tunneling probability between 0.2 and 0.5, the thickness of the coating of the second material is preferably in a range of 0.1 to 10 nanometers.

The second material may be lattice-matched to the third material.

The embedded, coated quantum dots can be arranged in a device further comprising an inorganic p-type layer and an inorganic n-type layer in superposed relationship, the coated quantum dots embedded in the third material being disposed between the p-type layer and the n-type layer. A conduction band edge of the p-type layer is preferably higher than the peak of the tunneling barrier in the case where the charge carrier is the electron. A valence band edge of the n-type layer is preferably lower than the peak of the tunneling barrier in the case where the charge carrier is the hole.

For each quantum dot, a thickness of the coating of the second material is preferably in a range of 0.1 to 10 nanometers. More preferably, within the range of 0.1 to 10 nanometers, the thickness of the coating of the second material is equal to no more than 10% of an average cross-sectional thickness of the first material through a center of a respective quantum dot.

The embedded, coated quantum dots may be arranged in a photosensitive device such as a solar cell.

### BRIEF DESCRIPTION OF THE DRAWINGS

FIG. 1 illustrates a intermediate band solar cell.

FIGS. 2A and 2B are energy-band diagrams for a cross-section of an inorganic quantum dot in an inorganic matrix material, with the lowest quantum state in the conduction band providing the intermediate band.

FIGS. 3A and 3B are energy-band diagrams for a cross-section of an inorganic quantum dot in an inorganic matrix material, with the highest quantum state in the valence band providing the intermediate band.

FIG. 4 is an energy band diagram for the intermediate band solar cell of FIG. 1, with inorganic quantum dots in an inorganic matrix material, and with the lowest quantum state in the conduction band providing the intermediate band.

FIG. 5 illustrates a cross-section of the array of quantum dots in the device in FIG. 1, as generally idealized and as formed in colloidal solutions.

FIG. 6 illustrates a cross-section of the array of quantum dots in the device in FIG. 1, if produced using the Stranski-Krastanow method.

FIG. 7 is an energy band diagram for a cross-section of an inorganic quantum dot in an inorganic matrix material, illustrating de-excitation and trapping of a passing electron.

FIG. 8 illustrates a cross-section of an array of quantum dots like that shown in FIG. 5, modified to include a tunneling barrier.

FIGS. 9A and 9B are energy-band diagrams for a cross-section of a quantum dot including tunneling barriers with a lowest quantum state above the band gap providing the intermediate band.

FIG. 10 is an energy band diagram for a solar cell based on the design in FIG. 1, with quantum dots modified to include the tunneling barrier, and with the lowest quantum state above the band gap providing the intermediate band.

FIGS. 11A and 11B are energy-band diagrams for a cross-section of a quantum dot including tunneling barriers with a highest quantum state below the band gap providing the intermediate band.

FIG. 12 is an energy band diagram for a solar cell based on the design in FIG. 1, with quantum modified to include the tunneling barrier, and with the highest quantum state below the band gap providing the intermediate band.

FIG. 13 illustrates a cross-section of the array of quantum dots modified to include the tunneling barrier, if produced using the Stranski-Krastanow method.

FIGS. 14 and 15 demonstrate tunneling through a rectangular barrier.

FIG. 16 demonstrates a triangular tunneling barrier.

FIG. 17 demonstrates a parabolic tunneling barrier.

The figures are not necessarily drawn to scale.

### DETAILED DESCRIPTION

One method being explored to improve the efficiency of solar cells is to use quantum dots to create an intermediate band within the bandgap of the solar cell. Quantum dots confine charge carriers (electrons, holes, and/or excitons) in three-dimensions to discrete quantum energy states. The cross-sectional dimension of each quantum dot is typically on the order of hundreds of Ångstroms or smaller. An intermediate-band structure is distinguishable, among other ways, by the overlapping wave functions between dots. The “intermediate” band is the continuous miniband formed by the overlapping wave functions. Although the wave functions overlap, there is no physical contact between adjacent dots.

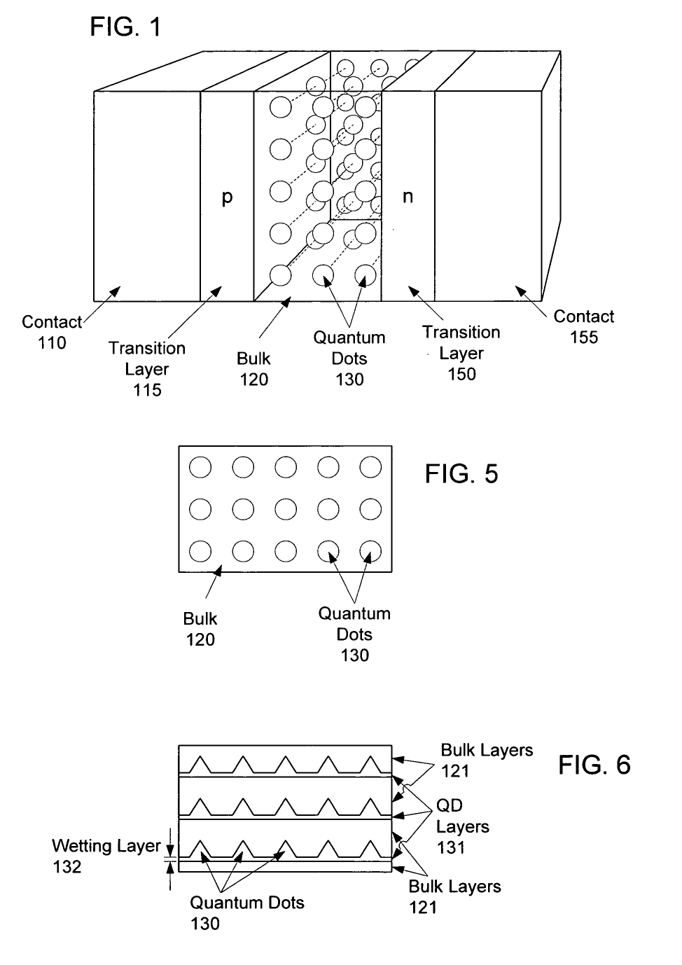

FIG. 1 illustrates an example of an intermediate-band device. The device comprises a first contact 110, a first transition layer 115, a plurality of quantum dots 130 embedded in a semiconductor bulk matrix material 120, an second transition layer 150, and a second contact 155.

In a device made of inorganic materials, one transition layer (115, 150) may be p-type, with the other transition layer being n-type. The bulk matrix material 120 and the quantum dots 130 may be intrinsic (not doped). The interfaces between the transition layers 115, 150 and the bulk matrix material 120 may provide rectification, polarizing current flow within the device. As an alternative, current-flow rectification may be provided by the interfaces between the contacts (110, 155) and the transition layers (115, 150).

Depending upon the arrangement of bands, the intermediate-band may correspond to a lowest quantum state above the band gap in the dots 130, or a highest quantum state below the band gap in the dots 130.

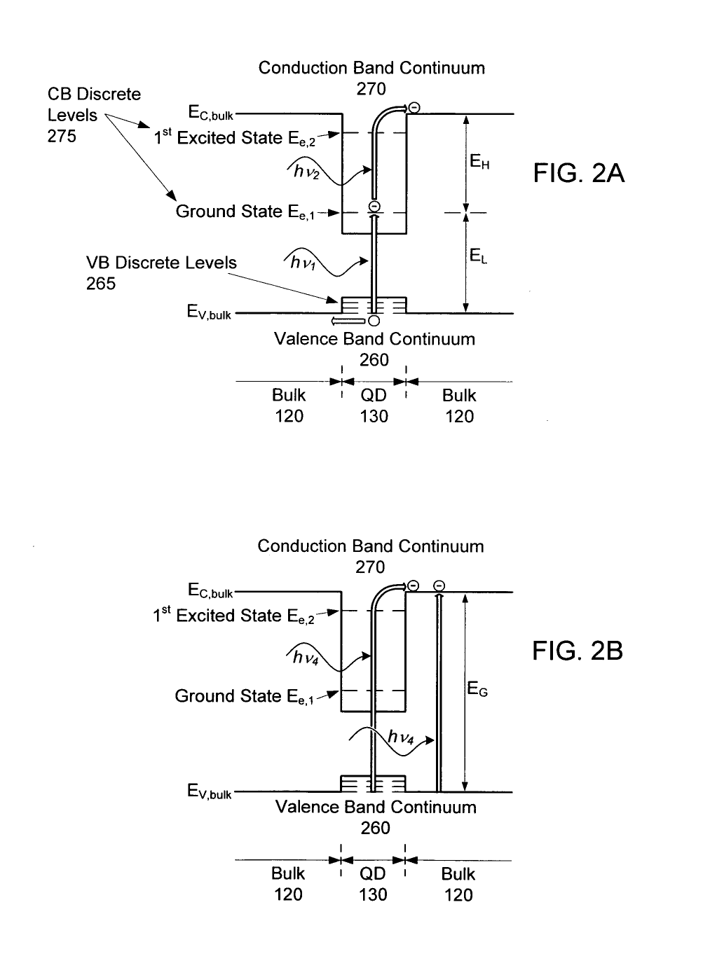

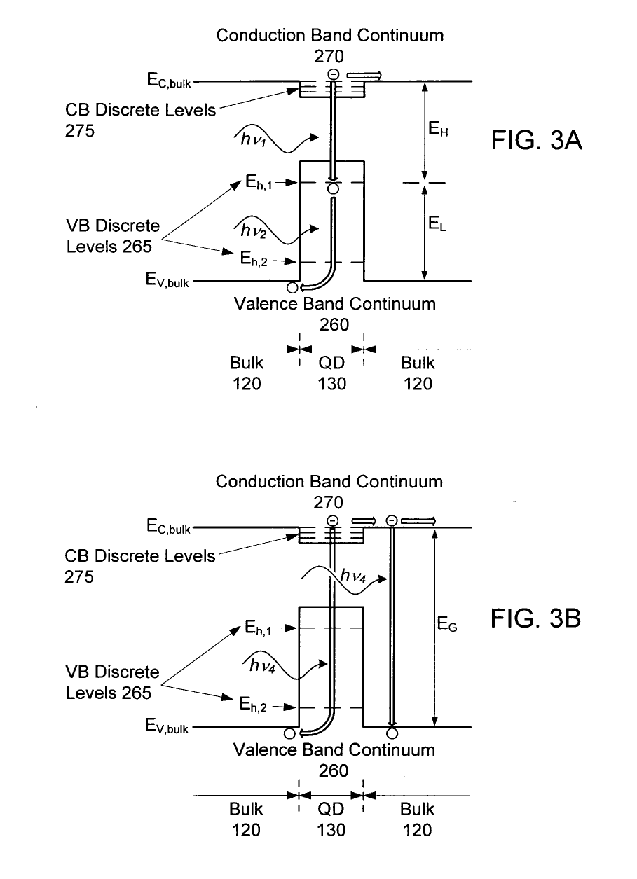

FIGS. 2A, 2B, 3A, and 3B are energy-band diagrams for cross-sections through example inorganic quantum dots 130 in an inorganic bulk matrix material 120. Within the dots, the conduction band is divided into quantum states 275, and the valence band is divided into quantum states 265.

In FIGS. 2A and 2B, the lowest quantum state (E_{e,1}) in the conduction band of a dot provides the intermediate band 280. Absorption of a first photon having energy hv₁ increases the energy of an electron by E_{L}, exciting the electron from the valence band to the conduction band electron ground state E_{e,1} of the quantum dot. Absorption of a second photon having energy hv₂ increases the energy of the electron by E_{H}, exciting the electron from the ground state E_{e,1} of the quantum dot to the conduction band edge of the bulk semiconductor 120, whereupon the electron is free to contribute to photocurrent. Absorption of a third photon having energy h V₄ increases the energy of an electron by E_{G}, exciting the electron directly from the valence band into the conduction band (which can also occur in the bulk matrix material 120 itself), whereupon the electron is free to contribute to photocurrent.

In FIGS. 3A and 3B, the highest quantum state (E_{h,1}) in the valence band provides the intermediate band 280. Absorption of a first photon having energy hv₁ increases the energy of an electron having an energy E_{h,1} by E_{H}, exciting the electron from the valence band side of the band gap into the conduction band, thereby creating an electron-hole pair. Conceptually, this can be thought of as exciting a hole in the conduction band by E_{H}, thereby moving the hole into the E_{h,1} quantum state. Absorption of a second photon having energy hv₂ increases the potential energy of the hole by E_{L}, exciting the electron from the ground state E_{h,1} of the quantum dot to the valence-band edge of the bulk semiconductor 120, whereupon the hole is free to contribute to photocurrent.

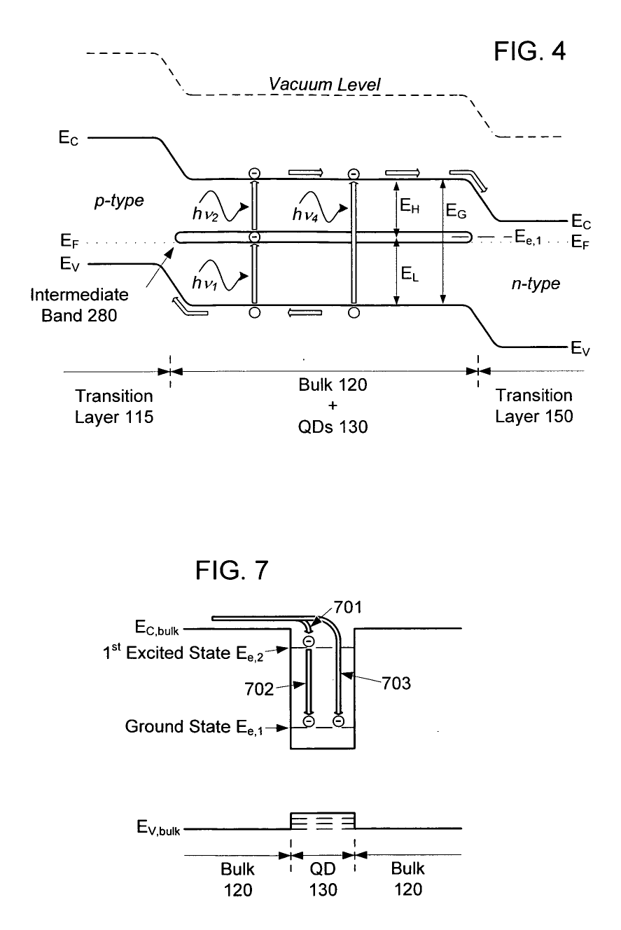

FIG. 4 illustrates an energy band diagram for the intermediate-band device, using an array of dots having the profile demonstrated in FIGS. 2A and 2B. The aggregate of the overlapping wave functions of the E_{e,1} energy state between adjacent quantum dots provides the intermediate band 280 between the conduction band edge (E_{C}) and the valence band edge (E_{V}) of the bulk matrix semiconductor 120. As in the same device if the quantum dots were omitted, absorption of photons of energy hv₄ generates electron-hole pairs, thereby producing photocurrent. The intermediate band 280 allows the absorption of two sub-band gap photons hv₁ and hv₂, leading to the creation of additional photocurrent. In FIG. 4, the transition layers 115 and 150 are arranged to create rectification.

FIG. 5 illustrates a cross-section of the device including an array of spherical quantum dots. In practice, the actual shape of the dots depends upon the choice of fabrication techniques. For example, inorganic quantum dots can be formed as semiconductor nanocrystallites in a colloidal solution, such as the “sol-gel” process known in the art. With some other arrangements, even if the actual dots are not true spheres, spheres may nonetheless provide an accurate model.

For example, an epitaxial method that has been successful in the creation of inorganic quantum dots in an inorganic matrix is the Stranski-Krastanow method (sometimes spelled Stransky-Krastanow in the literature). This method efficiently creates a lattice-mismatch strain between the dots and the bulk matrix while minimizing lattice damage and defects. Stranski-Krastanow is sometimes referred to as the “self-assembled quantum dot” (SAQD) technique.

The self-assembled quantum dots appear spontaneously, substantially without defects, during crystal growth with metal-organic chemical vapor deposition (MOCVD) or molecular beam epitaxy (MBE). Using growth conditions of the Stranski-Krastanow method, it is possible to create arrays and stacks of tiny dots (˜10 nm), self-ordered, with both high areal density (>10¹¹ cm⁻²) and optical quality. Self-ordered quantum dot (SOQD) techniques are able to create a three-dimensional quasi-crystal made up of a high density of defect-free quantum dots where radiative recombination is dominant.

FIG. 6 illustrates a cross-section of an intermediate-band device as fabricated by the Stranski-Krastanow method. A wetting layer 132 (e.g., one monolayer) is formed on the bulk matrix material 130. The material (e.g., InAs) used to form the wetting layer 132 has an intrinsic lattice spacing that is different from the bulk material (e.g., GaAs), but is grown as a strained layer aligned with the bulk lattice. Thereafter, spontaneous nucleation (˜1.5 monolayers) seeds the dots, followed by dot growth, resulting in quantum dot layers 131. Bulk 121 overgrowth (over the dots layers 131) is substantially defect free. The wetting layer between the dots, having a thickness which remains unchanged during dot formation, does not appreciably contribute to the electrical and optical properties of the device, such that the dots produced by the Stranski-Krastanov method are often illustrated as idealized spheres like those illustrated in FIG. 5 in the literature. (The wetting layer between the dots is not considered a “connection” between the dots).

For additional background on inorganic intermediate-band quantum dot devices and fabrication, see A. Marti et al., “Design constraints of quantum-dot intermediate band solar cell,” Physica E 14, 150-157 (2002); A. Luque, et al., “Progress towards the practical implementation of the intermediate band solar cell,” Conference Record of the Twenty-Ninth IEEE Photovoltaic Specialists Conference, 1190-1193 (2002); A. Marti et al., “Partial Filling of a Quantum Dot Intermediate Band for Solar Cells,” IEEE Transactions on Electron Devices, 48, 2394-2399 (2001); Y. Ebiko et al., “Island Size Scaling in InAs/GaAs Self-Assembled Quantum Dots,” Physical Review Letters 80, 2650-2653 (1998); and U.S. Pat. No. 6,583,436 B2 to Petroff et al. (Jun. 24, 2003); each of which is incorporated herein by reference for its description of state of the art.

While formation of an intermediate band improves device performance, the results have failed to approach the expected theoretical improvement in photocurrent. One problem that has been identified is the trapping by the quantum dots of free carriers that would otherwise contribute to photocurrent. FIG. 7 illustrates a free electron being trapped by the quantum dot 130 when the charge carrier decays to an excited state E_{e,2} (701) or to the ground state E_{e,1} (702, 703). This de-excitation process reduces photocurrent as the energy is absorbed into the lattice as phonons. Similar carrier deexcitation and trapping also happens with holes. Accordingly, to improve the performance of intermediate-band solar cells, there is a need to reduce charge carrier de-excitation due to charge trapping.

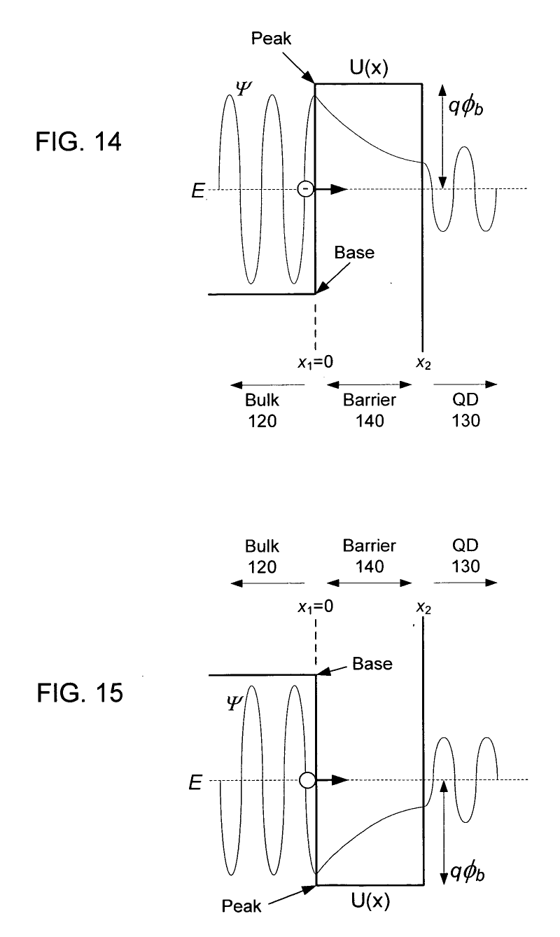

A solution for reducing de-excitation trapping is to encapsulate each quantum dot in a thin barrier shell to require carriers to perform quantum mechanical tunneling to enter the dot. In classical mechanics, when an electron impinges a barrier of higher potential, it is completely confined by the potential “wall.” In quantum mechanics, the electron can be represented by its wave function. The wave function does not terminate abruptly at a wall of finite potential height, and it can penetrate through the barrier. These same principles also apply to holes. The probability Tₜ of an electron or hole tunneling though a barrier of finite height is not zero, and can be determined by solving the Schrödinger equation. In accordance with Tₜ, electrons or holes impinging a barrier simply reappear on the other side of the barrier. For additional background discussion on the phenomena of quantum mechanical tunneling and the Schrödinger equation, see the discussion below with FIGS. 14-17, as well as Robert F. Pierret, “Modular Series On Solid State Devices Volume VI, Advanced Semiconductor Fundamentals,” Chapter 2, Elements of Quantum Mechanics, 25-51, Addison-Wesley Publishing (1989); and Kwok K. Ng, “Complete Guide to Semiconductor Devices,” 2d ed., Appendix B8, Tunneling, 625-627, Wiley-Interscience (2002). These sections of Pierret and Ng are incorporated herein by reference for their background explanation.

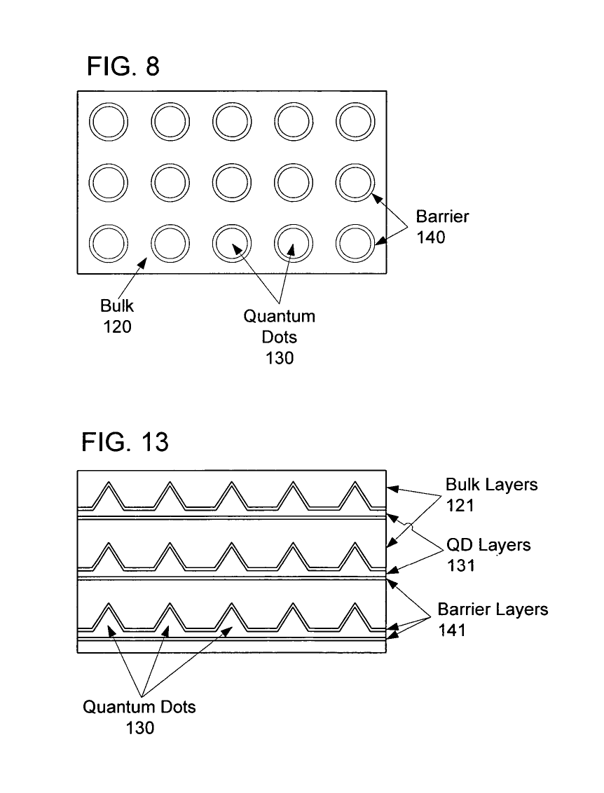

FIG. 8 is a generalized cross-section of the array of quantum dots, each quantum dot modified to include a tunneling barrier 140.

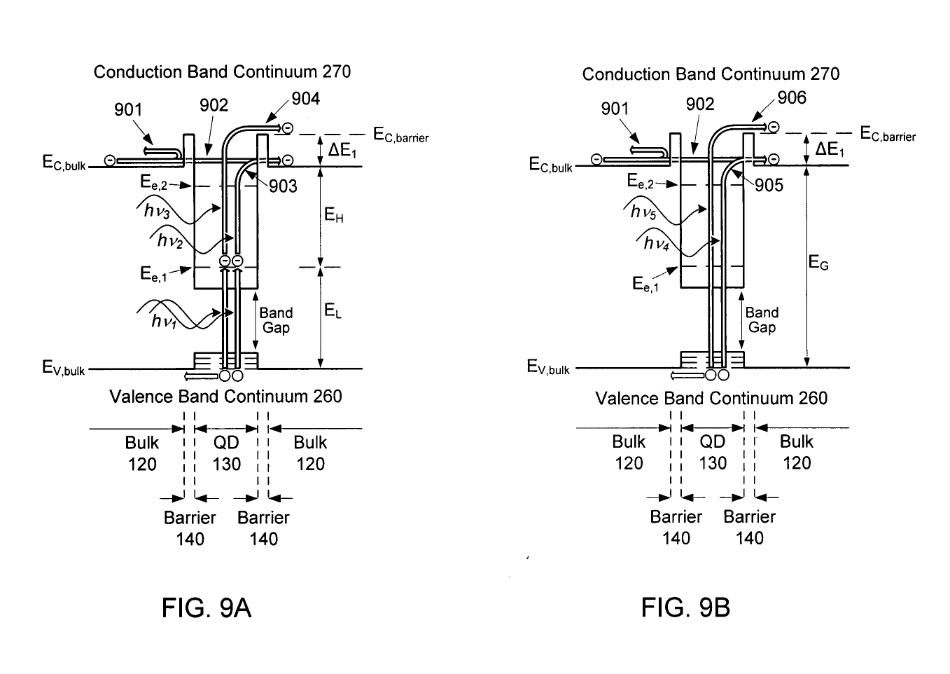

FIGS. 9A and 9B are energy band diagrams demonstrating a quantum dot modified to include a tunneling barrier 140 and having a quantum state above the band gap as the intermediate band 280. Some free electrons will be repelled (901) by the tunneling barrier. Such electrons are still available to contribute to photocurrent. Some free electrons will tunnel through the tunneling barrier (902) into and then out of the dot.

If the barrier 140 is viewed in the abstract, the probability that a free electron will tunnel through it is the same from either side of the barrier. For example, if a barrier presents a tunneling probability (Tₜ) of 0.5, there is a 50% chance that an electron (having an energy E) impinging on the barrier will tunnel. However, the small area of confinement within the quantum dot itself results in a much higher likelihood that an individual electron will escape before the relaxation and/or de-excitation cause the electron to fall to a lower energy state, since an electron having the energy of E_{C,bulk} or higher is continually impinging upon the barrier due to spatial confinement.

Electrons below the band gap within the dot are excited into a first quantum state (e.g., E_{e,1}) providing the intermediate band, by photons having energy hv₁. From the intermediate band, a photon having energy hv₂ may excite an electron to an energy where it will tunnel through (903) the tunneling barrier 140 to the E_{C,bulk} energy level of the bulk matrix material 120. In addition, a photon having an energy hv₃ may excite an electron over (904) the barrier 140. Electrons excited over the barrier have an excess energy of ΔE₁. This excess energy ΔE₁ is quickly lost as the electrons excited over the barrier decay to E_{C,bulk} energy level. This loss of excess energy is relatively minor in comparison to the energy lost to trapping without the tunneling barriers 140, and in general, occurs before the electron can be trapped by an adjacent dot (i.e., entering an adjacent dot over, rather than through, the tunneling barrier 140).

A photon of energy hv₄ may excite an electron directly from the E_{V,bulk} energy level to an energy level where it tunnels through (905) the tunneling barrier 140 into the E_{C,bulk} energy level of the bulk matrix material 120. Further, a photon having an energy hv₅ may excite an electron directly from the E_{V,bulk} energy level over (906) the barrier 140.

In order to further minimize the probability that a free electron passing (902) into and out of the dot will experience deexcitation, it is preferred that a second quantum state (e.g., E_{e,2}) is substantially equal to the E_{C,bulk} energy level of the bulk material. Specifically, the second quantum state is preferably within ±5 kT of the E_{C,bulk} energy level (k being the Boltzmann constant and T being the operating temperature), thereby creating an overlap between the second quantum state and the E_{C,bulk} energy level. A free electron, if entering a dot at an energy corresponding to a forbidden level within the dot is statistically more likely to be trapped due to deexcitation; by positioning the second quantum state in the dot within ±5 kT of the E_{C,bulk} energy level, the probability of trapping decreases.

Operating temperatures for inorganic photosensitive devices are commonly specified as having a range of T=−40° C. to +100° C. Thus, using +100° C. as a maximum limit and solving for ±5 kT (i.e., 5×1.3806505E−23(J/K)/1.602E−19(J/eV)×(T° C.+273.15)° K.), the second quantum state should be within ±0.16 eV of the conduction band edge of the bulk matrix material 120.

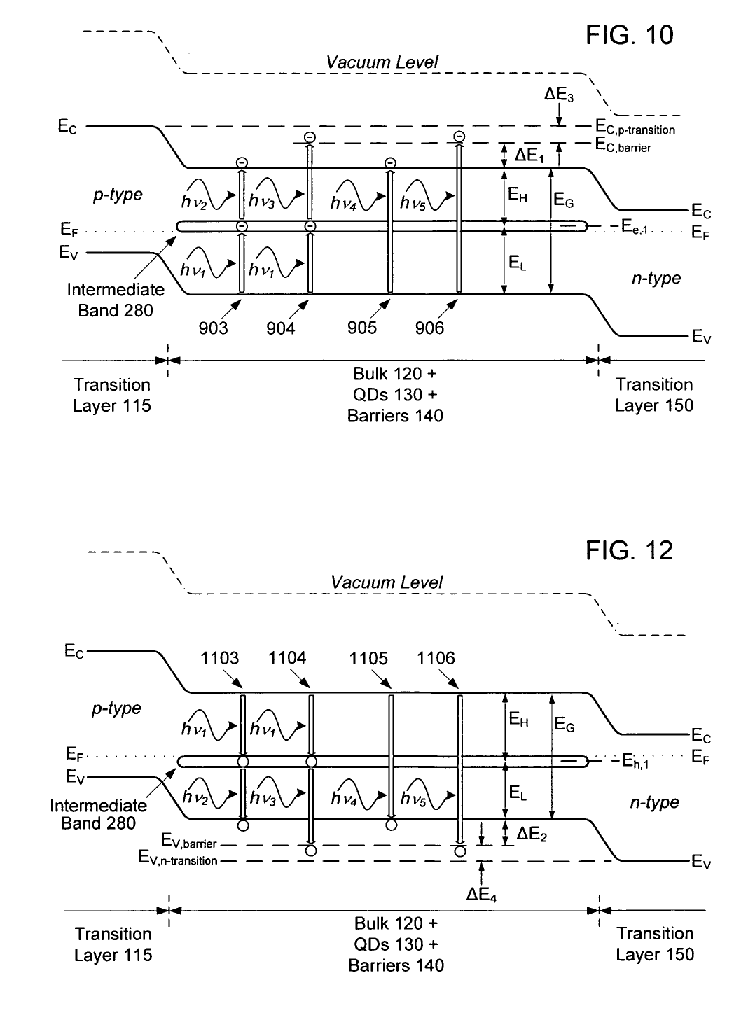

FIG. 10 is an energy band diagram for a device using the quantum dots from FIGS. 9A and 9B. The transition layers 115 and 150 are arranged to create rectification, thereby controlling the direction of current flow. Depending up the relative proximity between the quantum dots and the transition layer 115 and the time it takes for an electron that escapes a dot over the barrier 140 (904 or 906) to decay to E_{C,bulk} energy level, it is possible that for some configurations, an electron that escapes a dot over the barrier 140 might have sufficient energy to create a reverse current flow into the transition layer 115. Therefore, depending upon proximity and decay times, consideration should be given to ΔE₃, which is the difference between the conduction band edge (E_{C,p-transition}) of transition layer 115 and the conduction band edge (E_{C,barrier}) peak of the tunneling barrier 140. To maintain rectification at the interface with the transition layer 115, the E_{C,p-transition} band gap edge of the p-type transition layer 115 is preferably greater than a conduction band peak of the tunneling barriers (E_{C,barrier}).

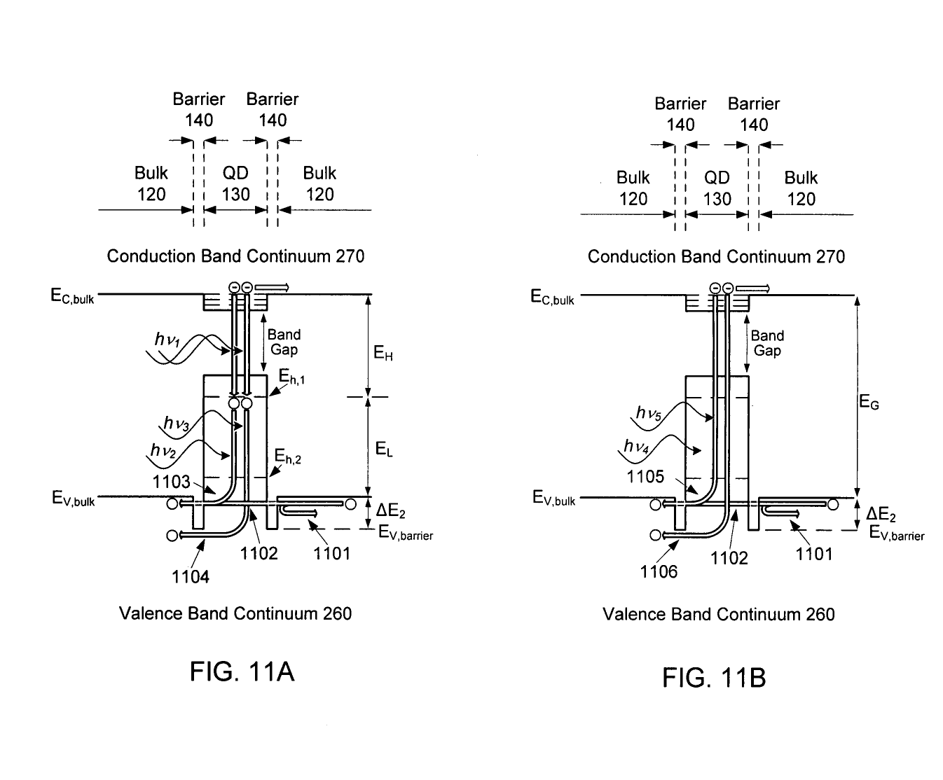

FIGS. 11A and 11B are energy band diagrams demonstrating a quantum dot modified to include a tunneling barrier 140 and having a quantum state below the band gap as the intermediate band 280. Some holes will be repelled (1101) by the tunneling barrier. Such holes are still available to contribute to photocurrent. Some holes will tunnel through the tunneling barrier (1102) into and then out of the dot.

As with the electron example discussed above, the small area of confinement within the quantum dot itself results in a much higher likelihood that an individual hole will escape before the relaxation and/or de-excitation cause the hole to “fall” to a higher energy state, since a hole having the energy of E_{V,bulk} or lower is continually impinging upon the barrier due to spatial confinement.

Holes above the band gap within the dot are excited into a first quantum state (e.g., E_{h,1}), providing the intermediate band, by photons having energy hv₁ (As with the concept discussed above with FIGS. 3A and 3B, excitation of hole in the conduction band is conceptually interchangeable with the generation of an electron-hole pair in the intermediate band, with the electron being excited into the conduction band and the hole being left behind in the intermediate band). From the intermediate band, a photon having energy hv₂ may excite the hole to an energy where it will tunnel through (1103) the tunneling barrier 140 into the E_{V,bulk} energy level of the bulk matrix material 120. In addition, a photon having an energy hv₃ may excite a hole over (1104) the barrier 140 (“over” being used since holes fall up). Holes excited over the barrier have an excess energy of ΔE₂. This excess energy ΔE₂ is quickly lost as the holes excited over the barrier decay to the E_{V,bulk} energy level. This loss of excess energy is relatively minor, in comparison to the energy lost to trapping without the tunneling barriers 140, and in general, occurs before the hole can be trapped by an adjacent dot (i.e., entering an adjacent dot over, rather than through, the tunneling barrier 140).

A photon of energy hv₄ may excite a hole directly from the E_{C,bulk} energy level to an energy level where it tunnels through (1105) the tunneling barrier 140 into the E_{V,bulk} energy level of the bulk matrix material 120. Further, a photon having an energy hv₅ may excite a hole directly from the E_{C,bulk} energy level over (1106) the barrier 140.

In order to further minimize the probability that a hole passing (1102) into and out of the dot will experience deexcitation, it is preferred that a second quantum state (e.g., E_{h,2}) of the valence band of the quantum dot is substantially equal to the E_{V,bulk} energy level of the bulk material. Specifically, the second quantum state should be within ±5 kT of the E_{V,bulk} energy level of the bulk material, thereby creating an overlap between the second quantum state and the E_{V,bulk} energy level. A hole, if entering a dot at an energy corresponding to a forbidden level within the dot is statistically more likely to be trapped due to deexcitation; by positioning the second quantum state in the dot within ±5 kT of the E_{V,bulk} energy level, the probability of trapping decreases.

FIG. 12 is an energy band diagram for a device using the quantum dots from FIGS. 11A and 11B. The transition layers 115 and 150 are again arranged to create rectification, thereby controlling the direction of current flow. Depending up the relative proximity between the quantum dots and the transition layer 150 and the time it takes for a hole that escapes a dot over the barrier 140 (1104 or 1106) to decay to E_{V,bulk} energy level, it is possible that for some configurations, a hole that escapes a dot over the barrier 140 might have sufficient energy to create a reverse current flow into the n-type transition layer 150. Therefore, depending upon proximity and decay times, consideration should be given to ΔE₄, which is the difference between the valence band edge (E_{V,n-transition}) of transition layer 150 and the valence band edge (E_{V,barrier}) peak of the tunneling barrier 140. To maintain rectification at the interface with the transition layer 150, the E_{V,n-transition} band gap edge of the transition layer 150 is preferably lower than a valence band peak of the tunneling barriers (E_{V,barrier}).

As used herein, the “peak” of a barrier for tunneling electrons is the highest energy edge of the E_{C,barrier} of the barrier, whereas the “base” is commensurate with the E_{C,bulk} energy level in the bulk matrix material at the interface with the barrier. The “peak” of a barrier for tunneling holes is the lowest energy edge of the E_{V,barrier} of the barrier, whereas the “base” is commensurate with the E_{V,bulk} energy level in the bulk matrix material at the interface with the barrier.

A characteristic of inorganic quantum dots that bears explaining and is apparent in FIGS. 9A and 9B is that in an inorganic quantum dot, the E_{e,1} quantum state may or may not correspond the conduction band edge (top of the band gap) of the quantum dot material. It is customary to illustrate the band gap of the dot material as though it were a bulk material, even if the band-gap edges of the material as arranged within the quantum dot are not “allowed” quantum states. The positions of allowed quantum states within an inorganic quantum dot are dependent on wave functions. As is known in the art, the position of the wave functions/quantum states can be engineered. As illustrated in FIGS. 9A and 9B, this may results in the E_{e,1} quantum state being positioned away from the band gap edge. In other words, the band gap edge in an inorganic quantum dot may not necessarily be an allowed quantum state. These characteristics also apply to the valence-band side of inorganic quantum dots (i.e., E_{h,1} in FIGS. 11A and 11B).

A characteristic of the inorganic bulk matrix material 120 may include the formation of a valence band continuum 260 and conduction band continuum 270 above and below the band gap edges of the inorganic bulk matrix material. These continuums are, in essence, a cloud of energy states, with a density of states decreasing with distance from the band gap edge. The presence of the continuums means that a charge carrier escaping a dot over a tunneling barrier may exit the dot into an allowed energy state, which is a consideration when determining how quickly the carrier will fall toward the band gap. For a typical density of states in a band continuum, the deexcitation loss of excess energy (ΔE₁, ΔE₂) is still likely to occur before the free electron can be trapped by an adjacent dot (i.e., entering an adjacent dot over, rather than through, the tunneling barrier 140).

For an inorganic dot in an inorganic matrix without a barrier layer (e.g., FIGS. 2 and 3), the band continuums 270, 260 over the dot essentially begin at E_{C,bulk} and E_{V,bulk}, respectively. In comparison, the presence of the barrier 140 may push the continuum 270 higher directly over the dot in FIGS. 9A and 9B, and may push the continuum 260 lower directly below the dot in FIGS. 11A and 11B.

FIG. 13 is a cross-section of an array of quantum dots based on the device in FIG. 1, if produced using the Stranski-Krastanow method and modified to include the tunneling barrier 140. A thin (e.g., at least one monolayer; for example, 0.1 to 10 nm) barrier layer 141 is grown (e.g., MBE, MOCVD), prior to deposition of the wetting layer 132. Then, after growth of the quantum dots 130, another barrier layer 141 is grown, thereby encapsulating each dot.

Preferably, the barrier layers 140, 141 are lattice-matched to the bulk matrix material 120, 121. A mismatch in strain increases the potential for defects. For example, a mismatch may result in an inconsistent lattice spacing within the barrier layer if the thickness of a thin barrier layer varies in places by as little as a monolayer, creating variations during the spontaneous nucleation that seeds the dots. Accordingly, lattice matching the barrier to the bulk matrix minimizes the chances of inhomogenieties between successive quantum dot layers and adjacent dots.

The devices described with FIGS. 8-13 may be achieved using several different material-type combinations.

For any of the inorganic quantum dots 130, 131 and inorganic bulk matrix materials 120, 121, examples of inorganic semiconductor materials include III-V compound semiconductors such as AlAs, AlSb, AlP, AlN, GaAs, GaSb, GaP, GaN, InAs, InSb, InP, and InN; II-VI compound semiconductors such as CdS, CdSe, CdTe, ZnO, ZnS, ZnSe, and ZnTe; other compound semiconductors such as PbS, PbSe, PbTe, and SiC; and the ternary and quaternary alloys of such compound semiconductors.

For any of the inorganic tunneling barriers 140, 141, examples of materials include the aforementioned inorganic semiconductor materials, as well as insulators such as oxides, nitrides, or oxynitrides. How to select materials having appropriate relative energies and how to select materials that lattice-match are well known in the art, and are not addressed here.

FIGS. 14-17 further demonstrate the principles of quantum mechanical tunneling. The explanation and equations below are based upon a discussion in “Complete Guide to Semiconductor Devices,” 2d ed., by Kwok K. Ng, Appendix B8, Tunneling, 625-627, Wiley-Interscience (2002). The explanation and equations have been modified to, among other things, accommodate holes in addition to electrons. Also, although the effective mass of a charge carrier in the quantum dot material and in the barrier material does not usually change significantly, the equations are modified to use a reduced effective mass adjusted for the change.

In general, without regard to whether organic and/or inorganic materials are used to build the photosensitive device, if the energy level E of a carrier relative to the barrier height is known, three parameters are required to determine the tunneling probability Tₜ for the carrier: the absolute value of the difference between the peak of the tunneling barrier and the energy of the carrier (φ_{b}), the thickness (Δx) of the barrier at the energy level of the carrier, and the potential profile U(x) of the barrier. The potential profile U(x) of the barrier is sometimes referred to as the “shape” of the barrier. An example of an electron tunneling through a rectangular barrier is illustrated in FIG. 14.

As is known in the art, to calculate the tunneling probability Tₜ for an electron, the wave function Ψ has to be determined from the Schrödinger equation:

$$\frac{{ⅆ}^{2} Ψ}{ⅆ x} + \frac{2 {m}_{r}^{*}}{{ℏ}^{2}} [ E - U ( x ) ] Ψ = 0 \qquad ( 1 )$$

where mᵣ* is the reduced effective mass of the charge carrier (in this case, an electron), h is the reduced Planck constant, and q is electron charge.

The reduced effective mass of the charge carrier is:

$$\frac{1}{{m}_{r}^{*}} = \frac{1}{{m}_{QD}^{*}} + \frac{1}{{m}_{barrier}^{*}} \qquad ( 2 )$$

where m*_{QD} is the effective mass of the charge carrier in the quantum dot, and m*_{barrier} is the effective mass of the charge carrier in the barrier material.

Since the potential profile U(x) of the barrier does not vary rapidly, Equation (1) can be simplified using the Wentzel-Kramers-Brillouin approximation and integrated to determine the wave function:

$$\vert \frac{Ψ ( {x}_{2} )}{Ψ ( {x}_{1} )} \vert = exp \{ - {\int }_{{x}_{1}}^{{x}_{2}} \sqrt{\frac{2 {m}_{r}^{*}}{{ℏ}^{2}} [ U ( x ) - E ]} ⅆ x \} \qquad ( 3 )$$

Since the probability of the electron's presence is proportional to the square of the wave function magnitude, the tunneling probability Tₜ is given by:

$${T}_{t} {\vert \frac{Ψ ( {x}_{2} )}{Ψ ( {x}_{1} )} \vert}^{2} = exp \{ - 2 {\int }_{{x}_{1}}^{{x}_{2}} \sqrt{\frac{2 {m}_{r}^{*}}{{ℏ}^{2}} [ U ( x ) - E ]} ⅆ x \} \qquad ( 4 )$$

For the case of the rectangular barrier illustrated in FIG. 14, solving Equation (4) for the tunneling probability is given by:

$${T}_{t} = exp \{ - 2 \sqrt{\frac{2 {m}_{r}^{*} q {ϕ}_{b}}{{ℏ}^{2}} Δ x} \} \qquad ( 5 )$$

Adapting Equation (5) to also apply to hole tunneling, as illustrated in FIG. 15 (in addition to electron tunneling illustrated in FIG. 14) by taking the absolute value of φ_{b}, and then rearranging the equation to solve for the thickness (Δx) of the barrier at the energy level of the carrier gives:

$$Δ x = \frac{- ln ( {T}_{t} ) ℏ}{2 \sqrt{2 {m}_{r}^{*} q \vert {ϕ}_{b} \vert}} \qquad ( 6 )$$

where m*ᵣ is the reduced effective mass of the charge carrier (electron or hole).

From a design point-of-view, the thickness Δx of the barrier is preferably selected based on the energy level at the base of the tunneling barrier. If the bulk matrix is an inorganic material having the conduction band continuum 270 and valence band continuum 260, the density of states generally suggests that a charge carrier having the energy level at the base of barrier will be the dominant carrier energy.

If the energy E of the charge carrier equals the energy level at the base of the tunneling barrier, then |φ_{b}| equals the absolute value of the height of the barrier, which is the difference between the energy levels at the peak and the base of the tunneling barrier. These energy levels are physical characteristic of the materials used for the bulk matrix material 120 and the barrier material 140. For example, in FIG. 14, the barrier height equals the E_{C,barrier} of the barrier material minus the E_{C,bulk} of the bulk matrix material; in FIG. 15, the barrier height equals the E_{V,barrier} of the barrier material minus the E_{V,bulk} of the bulk matrix material. The effective mass of the charge carrier in the barrier material m*_{barrier} and in the quantum dot material m*_{QD} are also physical characteristics of the respective materials. Moreover, the thickness Δx at the base of the tunneling barrier equals the physical thickness of the tunneling barrier layer 140, 141.

For example, if electrons are the tunneling charge carrier and approximating E as the energy level at the base of the barrier, Equation (6) can be expressed as:

$$Δ x = \frac{- ln ( {T}_{t} ) ℏ}{2 \sqrt{2 {m}_{r}^{*} q \vert {E}_{C , barrier} - {E}_{C , bulk} \vert}} \qquad ( 6 a )$$

Similarly, if holes tunnel through an inorganic barrier and approximating E as the energy level at the base of the barrier, Equation (6) can be expressed as:

$$Δ x = \frac{- ln ( {T}_{t} ) ℏ}{2 \sqrt{2 {m}_{r}^{*} q \vert {E}_{V , barrier} - {E}_{V , bulk} \vert}} \qquad ( 6 b )$$

Thus, if the materials are known, the preferred thickness Δx of the barrier layer 140 can be determined for any tunneling probability Tₜ.

Absent substantial diffusion or other material intermixing at the boundaries of the tunneling barrier 140, the potential profile U(x) of the tunneling barrier can almost always be approximated as rectangular. Furthermore, for any combination of materials, the thickness needed for the barrier layer is directly proportional to the negative of the natural log of the tunneling probability in accordance with:

$$Δ x ∝ \frac{- ln ( {T}_{t} ) ℏ}{\sqrt{2 {m}_{r}^{*} q \vert {ϕ}_{b} \vert}} \qquad ( 7 )$$

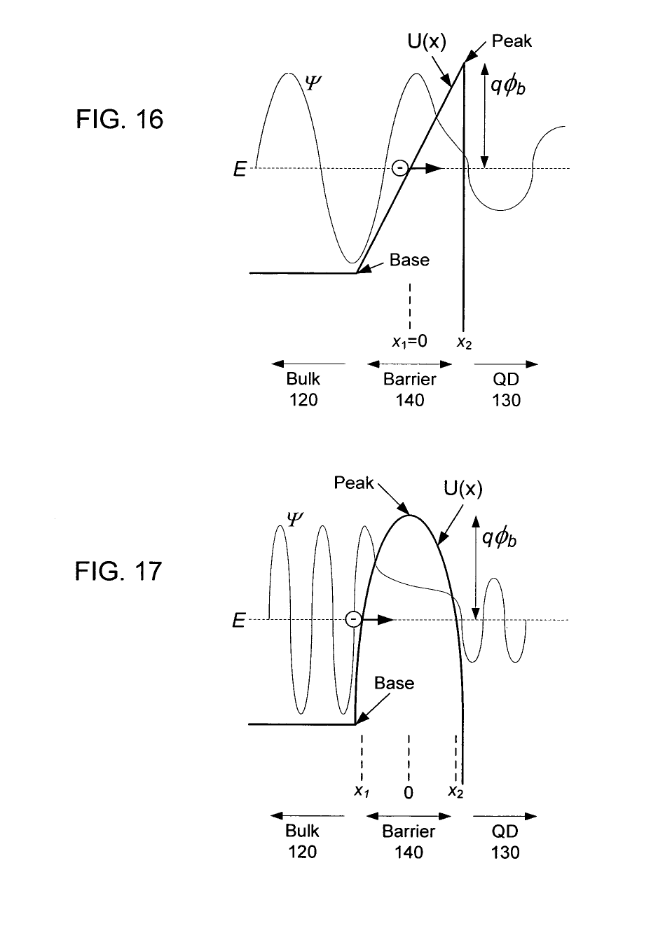

An equation to calculate barrier thickness can be derived for any function U(x). Without regard to the potential profile U(x) of the tunneling barrier, Equation (7) holds true. For example, FIG. 16 illustrates a triangular barrier and FIG. 17 illustrates a parabolic barrier.

In FIG. 16, potential can be described by:

$$U ( x ) - E = q {ϕ}_{b} ( \frac{x}{Δ x} ) \qquad ( 8 )$$

Solving Equation (4) with Equation (8), the tunneling probability is given by:

$${T}_{t} = exp \{ - \frac{4}{3} \sqrt{\frac{2 {m}_{r}^{*} q {ϕ}_{b}}{{ℏ}^{2}} Δ x} \} \qquad ( 9 )$$

Adapting Equation (9) to also apply to hole tunneling by taking the absolute value of φ_{b}, and then rearranging the equation to solve for the thickness (Δx) of the barrier at the energy level of the carrier gives:

$$Δ x = \frac{- 3 ln ( {T}_{ℓ} ) ℏ}{4 \sqrt{2 {m}_{r}^{*} q \vert {ϕ}_{b} \vert}} \qquad ( 10 )$$

In FIG. 17 potential can be described by:

$$U ( x ) - E = q {ϕ}_{b} ( 1 - \frac{4 {x}^{2}}{Δ {x}^{2}} ) \qquad ( 11 )$$

Solving Equation (4) with Equation (10), the tunneling probability is given by:

$${T}_{t} = exp \{ - \frac{π}{2} \sqrt{\frac{2 {m}_{r}^{*} q {ϕ}_{b}}{{ℏ}^{2}} Δ x} \} \qquad ( 12 )$$

Adapting Equation (12) to also apply to hole tunneling by taking the absolute value of φ_{b}, and then rearranging the equation to solve for the thickness (Δx) of the barrier at the energy level of the carrier gives:

$$Δ x = \frac{- 2 ln ( {T}_{ℓ} ) ℏ}{π \sqrt{2 {m}_{r}^{*} q \vert {ϕ}_{b} \vert}} \qquad ( 13 )$$

Thus, Equation (7) holds true, without regard to the potential profile U(x) of the barrier.

The tunneling probability Tₜ for barrier 140 is preferably between 0.1 and 0.9. A more precise probability Tₜ may be determined experimentally for any design by measuring the photocurrent output, thereby determining the efficiency to be gained. The more preferred range for Tₜ is between 0.2 and 0.5.

There is a balance to be struck between barrier height and barrier thickness for any given tunneling probability Tₜ. It may seem that making the barrier lower would increase efficiency by lessening the energy lost to deexcitation of carriers that hop out of a dot over the barrier, rather than tunneling out. However, this introduces another inefficiency since the barrier layer would need to be thicker for a same tunneling probability Tₜ, reducing the volume-percentage of the device dedicated to generating photocurrent. Even if the barriers are made of photoconductive materials, they would not be expected to appreciably contribute to photocurrent generation (due to their relatively large band gap). The end result is that thicker barriers take up space that would otherwise be composed of photoconductive materials, lowering photocurrent generation and efficiency. Accordingly, the preferred thickness limit for a tunneling barrier is between 0.1 to 10 nanometers. Within the range of 0.1 to 10 nanometers, the thickness of the tunneling barrier is preferably no more than 10% of the average cross-sectional thickness of a quantum dot, through a center of a quantum dot.

Whether holes or electrons are being used as the tunneling charge carrier, it is generally preferable that the energy levels of the opposite side of the band gap not create a trap for the opposite carrier. For example, referring to FIGS. 9A and 9B, the E_{V,barrier} of the barrier layer 140 is preferably within ±5 kT of the E_{V,bulk} of the bulk matrix 120. This general ±5 kT difference is also preferred between E_{C,barrier} and E_{C,bulk} on the conduction band side of the quantum dots in FIGS. 11A and 11B. The quantum dot material may be chosen to minimize the depth of the potential “trap” for the opposite carrier. Additionally, an energy state within the potential “trap” for the opposite side of the band gap is preferably positioned to keep an outermost quantum state within the trap within ±5 kT of the energy levels of the adjacent barrier layers 140, somewhat improving the probability that a passing electron or hole will pass right by without deexcitation.

The number of energy levels shown in the drawings within the quantum dots are simply examples. On the tunneling side, while there are preferably at least two quantum states (one forming the intermediate band and one positioned to overlap the energy level of the adjacent bulk matrix material), there may only be a single quantum state providing the intermediate band. Likewise, although the intermediate band is preferably formed by the quantum states closest to the band gap, a higher order energy state could be used. So long as the wave functions between adjacent dots overlap, a deciding factor as to whether a quantum state can function as an intermediate band is whether the two wavelengths required to pump a carrier by E_{L} and E_{H} will be incident on the dots.

As a practical matter, a band cannot function as an intermediate band if two wavelengths needed to pump the carrier through the band will never be incident on the quantum dots. For example, if one of the wavelengths needed for pumping either E_{L} or E_{H} is absorbed by the bulk matrix material, the barrier material, etc., it will not be incident on the quantum dots, even if the wavelength is incident on the photosensitive device itself. For many materials, this same problem limits the practicality of inter-band pumping through two quantum states (e.g., pumping from the valence band to an E_{e,1} state, then to an E_{e,2} state, and then into the conduction band). In any case, the tunneling barrier 140 and bulk matrix material 120 need to be substantially transparent to photons having energy E_{L} and E_{H}. Another consideration to balance in selecting materials is the efficiency and contribution to photocurrent of the transition of carriers directly across the bulk matrix band gap E_{G} (without passing into the intermediate band) in both the bulk matrix 120 and in the dots 130 themselves.

As described above, organic photosensitive devices of the present invention may be used to generate electrical power from incident electromagnetic radiation (e.g., photovoltaic devices). The device may be used to detect incident electromagnetic radiation (e.g., a photodetector or photoconductor cell). If used as a photoconductor cell, the transition layers 115 an 150 may be omitted.

Specific examples of the invention are illustrated and/or described herein. However, it will be appreciated that modifications and variations of the invention are covered by the above teachings and within the purview of the appended claims without departing from the spirit and scope of the invention.

1. A device comprising:
a plurality of quantum dots comprising a first inorganic material, each quantum dot being coated with a second inorganic material, the coated quantum dots being embedded in a matrix of a third inorganic material, at least the first and third materials being photoconductive semiconductors,
the second material being arranged as a tunneling barrier to require an electron at a conduction band edge in the third material to perform quantum mechanical tunneling to reach the first material within a respective coated quantum dot, and
a first quantum state above the band gap in each quantum dot being between the conduction band edge and a valence band edge of the third material in which the coated quantum dots are embedded, wave functions of the first quantum state of the plurality of quantum dots to overlap as an intermediate band.

2. The device of claim 1, the quantum dot further comprising a second quantum state, wherein the second quantum state is above the first quantum state and within ±0.16 eV of the conduction band edge of the third material.

3. The device of claim 1, a height of the tunneling barrier being an absolute value of an energy level difference between the conduction band edge of the third material and a peak of the tunneling barrier,
wherein a combination of the height and potential profile of the tunneling barrier and a thickness of the second material coating each quantum dot corresponds to a tunneling probability between 0.1 and 0.9 that the electron will tunnel into the first material within the respective coated quantum dot from the third material.

4. The device of claim 3, wherein for each quantum dot, the thickness of the coating of the second material is in a range of 0.1 to 10 nanometers.

5. The device of claim 3, wherein the combination of the height and potential profile of the tunneling barrier and the thickness of the second material coating each quantum dot corresponds to a tunneling probability between 0.2 and 0.5 that the electron will tunnel into the first material within the respective coated quantum dot from the third material.

6. The device of claim 5, wherein for each quantum dot, the thickness of the coating of the second material is in a range of 0.1 to 10 nanometers.

7. The device of claim 1, wherein the second material is lattice-matched to the third material.

8. The device of claim 1, further comprising an inorganic p-type layer and an inorganic n-type layer in superposed relationship, the coated quantum dots embedded in the third material being disposed between the p-type layer and the n-type layer, wherein a conduction band edge of the p-type layer is higher than the peak of the tunneling barrier.

9. The device of claim 1, wherein for each quantum dot, a thickness of the coating of the second material is in a range of 0.1 to 10 nanometers.

10. The device of claim 9, wherein for each quantum dot, the thickness of the coating of the second material is equal to no more than 10% of an average cross-sectional thickness of the first material through a center of a respective quantum dot.

11. The device of claim 1, wherein the device is a solar cell.

12. The device of claim 1, wherein the first inorganic material and the third inorganic material are each selected from the group consisting of III-V compound semiconductors, II-VI compound semiconductors, PbS, PbSe, PbTe, SiC, and ternary and quaternary alloys thereof.

13. The device of claim 12, wherein the second inorganic material is a semiconductor selected from the group consisting of III-V compound semiconductors, II-VI compound semiconductors, PbS, PbSe, PbTe, SiC, and ternary and quaternary alloys thereof.

14. The device of claim 12, wherein the second inorganic material is an electrical insulator selected from the group consisting of oxides, nitrides, and oxynitrides.

15. A device comprising:
a plurality of quantum dots comprising a first inorganic material, each quantum dot being coated with a second inorganic material, the coated quantum dots being embedded in a matrix of a third inorganic material, at least the first and third materials being photoconductive semiconductors,
the second material being arranged as a tunneling barrier to require a hole at a valence band edge in the third material to perform quantum mechanical tunneling to reach the first material within a respective coated quantum dot, and
a first quantum state below the band gap in each quantum dot being between a conduction band edge and the valence band edge of the third material in which the coated quantum dots are embedded, wave functions of the first quantum state of the plurality of quantum dots to overlap as an intermediate band.

16. The device of claim 15, the quantum dot further comprising a second quantum state, wherein the second quantum state is below the first quantum state and within ±0.16 eV of the valence band edge of the third material.

17. The device of claim 15, a height of the tunneling barrier being an absolute value of an energy level difference between the valence band edge of the third material and a peak of the tunneling barrier,
wherein a combination of the height and potential profile of the tunneling barrier and a thickness of the second material coating each quantum dot corresponds to a tunneling probability between 0.1 and 0.9 that the hole will tunnel into the first material within the respective coated quantum dot from the third material.

18. The device of claim 17, wherein for each quantum dot, the thickness of the coating of the second material is in a range of 0.1 to 10 nanometers.

19. The device of claim 17, wherein the combination of the height and potential profile of the tunneling barrier and the thickness of the second material coating each quantum dot corresponds to a tunneling probability between 0.2 and 0.5 that the hole will tunnel into the first material within the respective coated quantum dot from the third material.

20. The device of claim 19, wherein for each quantum dot, the thickness of the coating of the second material is in a range of 0.1 to 10 nanometers.

21. The device of claim 15, wherein the second material is lattice-matched to the third material.

22. The device of claim 15, further comprising an inorganic p-type layer and an inorganic n-type layer in superposed relationship, the coated quantum dots embedded in the third material being disposed between the p-type layer and the n-type layer, wherein a valence band edge of the n-type layer is lower than the peak of the tunneling barrier.

23. The device of claim 15, wherein for each quantum dot, a thickness of the coating of the second material is in a range of 0.1 to 10 nanometers.

24. The device of claim 23, wherein for each quantum dot, the thickness of the coating of the second material is equal to no more than 10% of an average cross-sectional thickness of the first material through a center of a respective quantum dot.

25. The device of claim 15, wherein the device is a solar cell.

26. The device of claim 15, wherein the first inorganic material and the third inorganic material are each selected from the group consisting of III-V compound semiconductors, II-VI compound semiconductors, PbS, PbSe, PbTe, SiC, and ternary and quaternary alloys thereof.

27. The device of claim 26, wherein the second inorganic material is a semiconductor selected from the group consisting of III-V compound semiconductors, II-VI compound semiconductors, PbS, PbSe, PbTe, SiC, and ternary and quaternary alloys thereof.

28. The device of claim 26, wherein the second inorganic material is an electrical insulator selected from the group consisting of oxides, nitrides, and oxynitrides.
